(19) United States
(12) Patent Application Publication
(10) Pub. No.: US 2021/0263097 A1
(43) Pub. Date: Aug. 26, 2021

(54) ELECTRONIC COMPONENT HANDLER, ELECTRONIC COMPONENT TESTER, AND METHOD OF CHECKING CONDITION OF ELECTRONIC COMPONENT HANDLER

(71) Applicant: SEIKO EPSON CORPORATION, Tokyo (JP)

(72) Inventors: Fuyumi TAKATA, AZUMINO-SHI (JP); Makoto YANAGISAWA, MATSUMOTO-SHI (JP); Satoshi NAKAMURA, MATSUMOTO-SHI (JP); Noriaki KOTANI, SUWA-GUN HARA-MURA (JP)

(21) Appl. No.: 17/183,384

(22) Filed: Feb. 24, 2021

(30) Foreign Application Priority Data
Feb. 25, 2020 (JP) 2020-029122

(51) Int. Cl. G01R 31/28

(52) U.S. Cl. CPC G01R 31/2891

(57) ABSTRACT

An electronic component handler includes a container mount member on which a tray with an IC device mounted thereon is placed, a support member as a part of a reinforcing member supporting the container mount member and extending along a first axis, a first transport robot having a first device transport head that holds the IC device and moves along a second rail, and a first sensor placed in the first device transport head, wherein a first marker and a second marker are provided on the support member and positions of the first marker and the second marker are detected by the first sensor.

The present application is based on, and claims priority from JP Application Serial Number 2020-029122, filed Feb. 25, 2020, the disclosure of which is hereby incorporated by reference herein in its entirety.

### BACKGROUND

### 1. Technical Field

The present disclosure relates to an electronic component handler, an electronic component tester, and a method of checking a condition of an electronic component handler.

### 2. Related Art

For electric characteristic tests of electronic components such as ICs (Integrated Circuits) and semiconductor devices, there are electronic component handlers that sort and store the electronic components according to test results as good items or defective items.

For example, JP-A-10-156639 discloses a method of adjusting a position of a hand of a moving unit of a horizontal transport auto handler. According to JP-A-10-156639, an IC dummy piece with a hole is mounted on a tray or a carrier, the hole is explored with the end of the hand, and the position of the hand is corrected using coordinates of the hole as correct coordinates. Further, both the tray and the IC dummy piece are detachably provided.

However, in JP-A-10-156639, both the IC dummy piece and the tray or carrier on which the IC dummy piece is set are detachably configured and, when these are detached or attached in incorrect positions, it is difficult to accurately align X and Y axes of a transport robot with reference to these positions.

### SUMMARY

An electronic component handler includes a container mount member on which a container with an electronic component mounted thereon is placed, a support member supporting the container mount member and extending along a first axis, a transport robot having a moving unit that holds the electronic component and moves, and a sensor placed in the moving unit, wherein a marker is provided on the support member and the sensor detects a position of the marker.

An electronic component tester includes a test unit that tests the electronic component, and the above described electronic component handler.

A method of checking a condition of an electronic component handler is a method of checking a condition of an electronic component handler that transports an electronic component, including detecting and outputting a position of a first marker of a support member as a first measurement coordinate to a control section by a sensor of a transport robot, comparing a first reference coordinate stored in advance with the first measurement coordinate by the control section, detecting and outputting a position of a second marker of the support member as a second measurement coordinate to the control section by the sensor of the transport robot, comparing first axis components between the first measurement coordinate and the second measurement coordinate by the control section, and, when a difference between the first measurement coordinate and the first reference coordinate is equal to or larger than a predetermined value or when a difference between the first axis components of the first measurement coordinate and the second measurement coordinate is equal to or larger than a predetermined value, outputting a condition in which a moving unit of the transport robot is displaced.

### BRIEF DESCRIPTION OF THE DRAWINGS

FIG. 1 is a schematic perspective view showing an electronic component tester according to a first embodiment from a front side.

FIG. 2 is a schematic plan view showing an operating state of the electronic component tester.

FIG. 3 is a schematic plan view showing an installation of robots.

FIG. 4 is a schematic side view showing a reinforcing member.

FIG. 5 is a side view showing a device transport head.

FIG. 6 is a schematic diagram for explanation of a method of detecting a marker.

FIG. 7 is a schematic diagram for explanation of the method of detecting the marker.

FIG. 8 is a schematic diagram for explanation of the method of detecting the marker.

FIG. 9 is a schematic diagram for explanation of a method of detecting coordinates of the marker.

FIG. 10 is a schematic diagram for explanation of the method of detecting the coordinates of the marker.

FIG. 11 is an electric block diagram showing a configuration of a control section.

FIG. 12 is a flowchart of a method of detecting a coordinate shift.

FIG. 13 is a side view showing a device transport head according to a second embodiment.

FIG. 14 is a schematic diagram for explanation of a method of detecting a support member center line according to a fifth embodiment.

FIG. 15 is a schematic diagram for explanation of the method of detecting the support member center line.

### DESCRIPTION OF EXEMPLARY EMBODIMENTS

### First Embodiment

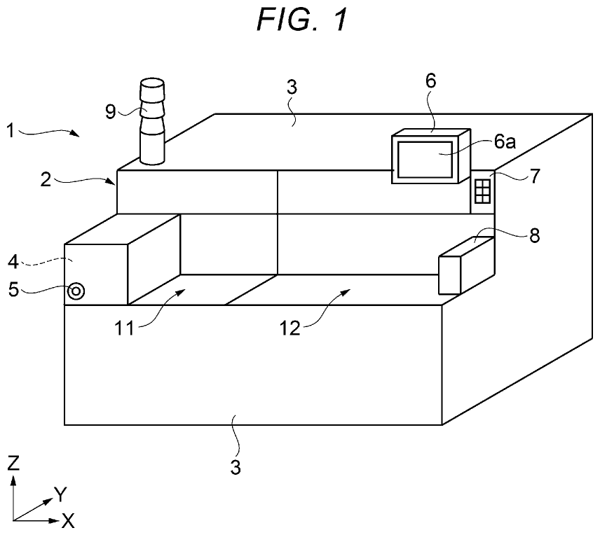

As shown in FIG. 1, three axes orthogonal to one another are referred to as “X-axis”, “Y-axis”, and “Z-axis”. Further, an X-Y plane containing the X-axis and the Y-axis is horizontal and the Z-axis is along the vertical directions. Furthermore, directions parallel to the X-axis are referred to as “X directions”. Directions parallel to the Y-axis are referred to as “Y directions”. Directions parallel to the Z-axis are referred to as “Z directions”. The sides pointed by arrows of the respective directions are referred to as “positive” and the opposite sides are referred to as “negative”.

“Horizontal” is not limited to complete horizontal, but includes slightly inclined states relative to horizontal unless transport of electronic components is hindered. “Vertical” is not limited to complete vertical, but includes slightly inclined states relative to vertical unless transport of electronic components is hindered. The inclination angles in the slightly inclined states are less than 5°.

The upside in FIG. 1, i.e., the positive side in the Z direction is referred to as “upper” or “above” and the downside, i.e., the negative side in the Z direction is referred to as “lower” or “below”.

An electronic component tester 1 having an electronic component handler 2 is an apparatus that performs tests and examinations of electric characteristics of electronic components such as IC (Integrated Circuit) devices e.g. BGA (Ball Grid Array) packages. The test of electric characteristics is referred to as “electric characteristic test”. As shown in FIG. 1, the electronic component tester 1 includes the electronic component handler 2 inside. The electronic component handler 2 is an apparatus that transports electronic components.

The electronic component handler 2 is covered by a cover 3. The electronic component tester 1 includes a control section 4 at the negative side in the Y direction and the negative side in the X direction. The control section 4 controls operations of the electronic component tester 1. A speaker 5 is placed near the control section 4. In the electronic component tester 1, a monitor 6, an operation panel 7, and a mouse stand 8 are placed at the negative side in the Y direction and the positive side in the X direction. Various kinds of information is displayed on a display screen 6a of the monitor 6. The monitor 6 has the display screen 6a including e.g. a liquid crystal screen and is placed in the upper part at the front side of the electronic component tester 1. The mouse stand 8 on which a mouse is mounted is provided on the right side of a tray removal region 12 in FIG. 1. An operator operates the mouse on the mouse stand 8 and the operation panel 7 to set operating conditions etc. of the electronic component tester 1 and input details of an instruction. The operation panel 7 is an interface for commanding desired operations to the electronic component tester 1.

The electronic component tester 1 includes a signal lamp 9 at the negative side in the Y direction and the negative side in the X direction. The signal lamp 9 and the speaker 5 report the operating states etc. of the electronic component tester 1. The signal lamp 9 reports the operating states etc. of the electronic component tester 1 by combinations of colors of emitted lights. The signal lamp 9 is placed in the upper part of the electronic component tester 1.

In the electronic component tester 1, a tray feed region 11 and the tray removal region 12 are provided at the negative side in the Y direction. The operator feeds trays on which electronic components are arranged to the tray feed region 11. The electronic component tester 1 takes in the tray from the tray feed region 11 and performs the electric characteristic test. The electronic component tester 1 ejects the trays on which the electronic components after the electric characteristic test are arranged to the tray removal region 12.

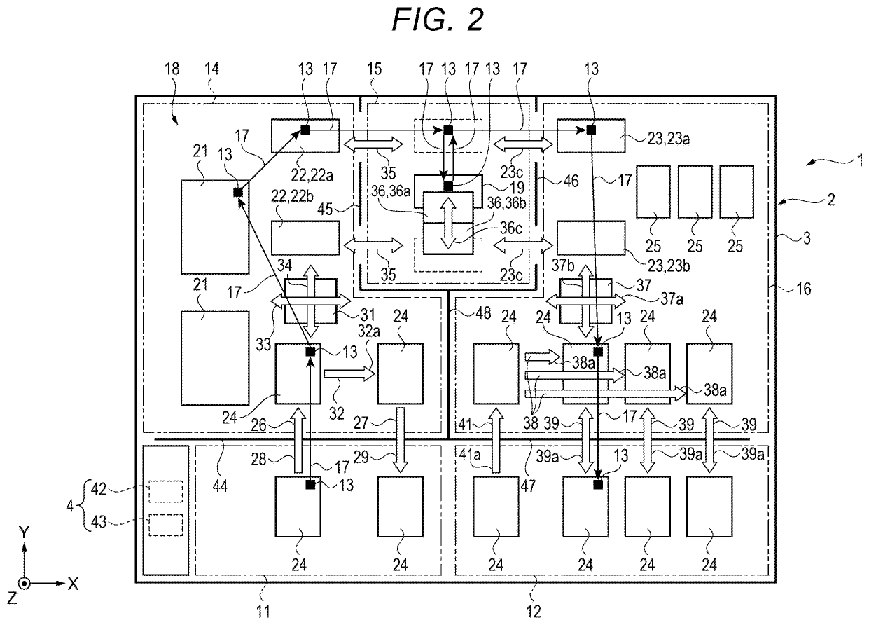

As shown in FIG. 2, for convenience of explanation, a case of using IC devices 13 as electronic components will be representatively explained. The IC device 13 has a flat plate shape. A plurality of semispherical terminals are placed on a lower surface of the IC device 13.

The IC device 13 includes e.g. an LSI (Large Scale Integration), a CMOS (Complementary Metal Oxide Semiconductor), a CCD (Charge Coupled Device), a module IC in which a plurality of modules are packaged, a quartz crystal device, a pressure sensor, an inertial sensor, an acceleration sensor, a gyro sensor, and a fingerprint sensor.

The electronic component handler 2 includes the tray feed region 11, a device feed region 14, a test region 15, a device collection region 16, and the tray removal region 12. These respective regions are divided by walls. The IC device 13 sequentially passes through the respective regions in directions of first arrows 17 from the tray feed region 11 to the tray removal region 12 and a test is performed in the test region 15 along the route. The electronic component tester 1 includes the electronic component handler 2 having a transport section 18 as a transport robot that transports the IC device 13 through the respective regions, a test unit 19 that performs a test within the test region 15, and the control section 4 including an industrial computer.

The electronic component tester 1 is used with the side at which the tray feed region 11 and the tray removal region 12 are placed as a front side and the side at which the test region 15 is placed as a rear side.

The electronic component tester 1 is used with a unit called “change kit”, which is replaced with respect to each type of the IC device 13, mounted thereon in advance. The change kit includes e.g. a temperature adjustment unit 21, a device feed unit 22, and a device collection unit 23. Other units replaced with respect to each type of the IC device 13 than the change kit includes e.g. trays 24 as containers, collection trays 25, and the test unit 19. The trays 24 are containers on which the IC devices 13 are mounted.

The tray feed region 11 is a feed part where the tray 24 on which a plurality of untested IC devices 13 are arranged is fed. On the tray feed region 11, a plurality of the trays 24 are stacked and mounted. In each tray 24, a plurality of concave portions are arranged in a matrix form. In the respective concave portions, the IC devices 13 are held one by one.

In the device feed region 14, the plurality of IC devices 13 on the tray 24 transported from the tray feed region 11 are respectively transported to the device feed unit 22. The IC devices 13 are transported from the device feed region 14 to the test region 15 by the device feed unit 22. Over the tray feed region 11 and the device feed region 14, a first tray transport mechanism 26 and a second transport mechanism 27 that transport the trays 24 in horizontal directions one by one are provided. The first tray transport mechanism 26 forms a part of the transport section 18. The first tray transport mechanism 26 moves the tray 24 with the IC devices 13 mounted thereon to the positive side in the Y direction, i.e., a direction of a second arrow 28 in FIG. 2. Thereby, the IC devices 13 are fed into the device feed region 14. Further, the second transport mechanism 27 moves the empty tray 24 to the negative side in the Y direction, i.e., a direction of a third arrow 29 in FIG. 2. The second transport mechanism 27 moves the empty tray 24 from the device feed region 14 to the tray feed region 11.

In the device feed region 14, the temperature adjustment units 21, a first device transport head 31 as a moving unit, a tray transport mechanism 32, and the device feed units 22 are provided. The temperature adjustment unit 21 is also called a soak plate (in English) or a jun wen ban (in Chinese). The device feed unit 22 moves over the device feed region 14 and the test region 15.

A plurality of IC devices 13 are mounted on the temperature adjustment unit 21. The temperature adjustment unit 21 may collectively heat or cool the mounted IC devices 13. The temperature adjustment unit 21 heats or cools the IC devices 13 in advance to adjust the devices at temperature suitable for the electric characteristic test.

In the embodiment, for example, the two temperature adjustment units 21 are placed in the Y directions. The IC devices 13 on the tray 24 transported from the tray feed region 11 by the first tray transport mechanism 26 are transported to one of the temperature adjustment units 21.

The first device transport head 31 includes a mechanism of holding the IC devices 13. The first device transport head 31 moves the IC devices 13 in the X directions, the Y directions, and the Z directions within the device feed region 14. The first device transport head 31 forms a part of the transport section 18. The first device transport head 31 transports the IC devices 13 between the tray 24 transported from the tray feed region 11 and the temperature adjustment unit 21. The first device transport head 31 transports the IC devices 13 between the temperature adjustment unit 21 and the device feed unit 22. Note that, in FIG. 2, the movement of the first device transport head 31 in the X directions is shown by a fourth arrow 33 and the movement of the first device transport head 31 in the Y directions is shown by a fifth arrow 34.

The IC devices 13 at the temperature adjusted in the temperature adjustment unit 21 are mounted on the device feed unit 22. The device feed unit 22 transports the IC devices 13 to a vicinity of the test unit 19. The device feed unit 22 is called “feed shuttle plate” or “feed shuttle”. Also, the device feed units 22 form a part of the transport section 18. The device feed unit 22 has concave portions on which the IC devices 13 are held and mounted.

The device feed unit 22 reciprocates in the X directions, i.e., directions of a sixth arrow 35 between the device feed region 14 and the test region 15. Thereby, the device feed unit 22 transports the IC devices 13 from the device feed region 14 to the vicinity of the test unit 19 in the test region 15. The IC devices 13 are removed by a second device transport head 36 in the test region 15, and then, the device feed unit 22 returns to the device feed region 14 again.

The two device feed units 22 are placed in the Y directions. The device feed unit 22 at the positive side in the Y direction is referred to as “first device feed unit 22a”. The device feed unit 22 at the negative side in the Y direction is referred to as “second device feed unit 22b”. The IC devices 13 on the temperature adjustment unit 21 are transported to the first device feed unit 22a or the second device feed unit 22b within the device feed region 14 by the first device transport head 31. The device feed unit 22 can heat or cool the IC devices 13 mounted on the device feed unit 22. The IC devices 13 at the temperature adjusted by the temperature adjustment unit 21 are transported to the vicinity of the test unit 19 in the test region 15 at the maintained adjusted temperature. Further, the device feed units 22 and the temperature adjustment units 21 are electrically grounded to a chassis.

The tray transport mechanism 32 is a mechanism that transports the empty tray 24 after removal of all IC devices 13 to the positive side in the X direction, i.e., a direction of a seventh arrow 32a within the device feed region 14. After transport in the direction of the seventh arrow 32a, the empty tray 24 is returned from the device feed region 14 to the tray feed region 11 by the second transport mechanism 27.

The test region 15 is a region in which the IC devices 13 are tested. In the test region 15, the test unit 19 that tests the IC devices 13 and the second device transport heads 36 are provided.

The second device transport heads 36 form a part of the transport section 18 and can heat or cool the held IC devices 13. The second device transport head 36 transports the IC devices 13 at the adjusted temperature maintained within the test region 15.

The second device transport heads 36 are supported reciprocably in the Y directions and the Z directions within the test region 15, and form a part of a mechanism called “index arm”. The second device transport head 36 lifts the IC devices 13 and transports and mounts the devices onto the test unit 19 from the device feed unit 22.

In FIG. 2, the reciprocation of the second device transport heads 36 in the Y directions is shown by an eighth arrow 36c. The second device transport heads 36 serve to transport the IC devices 13 from the first device feed unit 22a to the test unit 19 and transport the IC devices 13 from the second device feed unit 22b to the test unit 19. Further, the second device transport heads 36 are supported reciprocably in the Y directions.

The two second device transport heads 36 are placed in the Y directions. The second device transport head 36 at the positive side in the Y direction is referred to as “third device transport head 36a”. The second device transport head 36 at the negative side in the Y direction is referred to as “fourth device transport head 36b”. The third device transport head 36a serves to transport the IC devices 13 from the first device feed unit 22a to the test unit 19. The fourth device transport head 36b serves to transport the IC devices 13 from the second device feed unit 22b to the test unit 19. The third device transport head 36a serves to transport the IC devices 13 from the test unit 19 to a first device collection unit 23a. The fourth device transport head 36b serves to transport the IC devices 13 from the test unit 19 to a second device collection unit 23b.

The IC device 13 is mounted on the test unit 19 and the test unit 19 tests electric characteristics of the IC device 13. In the test unit 19, a plurality of probe pins to be electrically coupled to the terminals of the IC device 13 are provided. The terminals of the IC device 13 and the probe pins are electrically coupled. Then, the test unit 19 performs a test of the IC device 13. The test of the IC device 13 is performed based on a program stored in a test control unit provided in a tester electrically coupled to the test unit 19. Also, in the test unit 19, the IC device 13 may be heated or cooled and the IC device 13 may be adjusted at a temperature suitable for the test.

The device collection region 16 is a region in which the plurality of IC devices 13 after test are collected. In the device collection region 16, the collection trays 25, a fifth device transport head 37, and third tray transport mechanisms 38 are provided. The device collection units 23 moving over the test region 15 and the device collection region 16 are further provided. The empty trays 24 are prepared in the device collection region 16.

On the device collection unit 23, the IC devices 13 after test are placed. The device collection unit 23 transports the IC devices 13 to the device collection region 16. The device collection unit 23 is also referred to as “collection shuttle plate” or simply “collection shuttle”. Also, the device collection units 23 form a part of the transport section 18.

The device collection units 23 are supported reciprocably in the X directions, i.e., along directions of ninth arrows 23c between the test region 15 and the device collection region 16. The two device collection units 23 are placed in the Y directions. The device collection unit 23 at the positive side in the Y direction is the first device collection unit 23a. The device collection unit 23 at the negative side in the Y direction is the second device collection unit 23b. The IC devices 13 on the test unit 19 are transported and mounted onto the first device collection unit 23a and the second device collection unit 23b. The second device transport heads 36 serve to transport the IC devices 13 from the test unit 19 to the first device collection unit 23a and transport the IC devices 13 from the test unit 19 to the second device collection unit 23b. Further, the device collection units 23 are electrically grounded to the chassis.

On the collection trays 25, the IC devices 13 tested in the test unit 19 are placed. The IC devices 13 are fixed to the collection trays 25 not to move within the device collection region 16. Even in the device collection region 16 where a relatively large number of various movable units including the fifth device transport head 37 are placed, the tested IC devices 13 are stably mounted on the collection trays 25. Three collection trays 25 are placed along the X directions.

Further, the four empty trays 24 are placed along the X directions. The tested IC devices 13 are mounted on the empty trays 24. The IC devices 13 on the device collection unit 23 are transported and mounted onto one of the collection trays 25 or the empty trays 24. The IC devices 13 are sorted and collected with respect to each test result.

The fifth device transport head 37 is supported reciprocably in the X directions and the Y directions within the device collection region 16. The fifth device transport head 37 has a portion also movable in the Z directions. The fifth device transport head 37 forms a part of the transport section 18. The fifth device transport head 37 transports the IC devices 13 from the device collection unit 23 to the collection tray 25 or the empty tray 24. In FIG. 2, the movement of the fifth device transport head 37 in the X directions is shown by a tenth arrow 37a and the movement of the fifth device transport head 37 in the Y directions is shown by an eleventh arrow 37b.

The third tray transport mechanism 38 is a mechanism of transporting the empty tray 24 transported from the tray removal region 12 in the X directions, i.e., directions of twelfth arrows 38a within the device collection region 16. After the transport, the empty tray 24 is placed in a position where the IC devices 13 are collected.

In the tray removal region 12, the tray 24 on which the plurality of tested IC devices 13 are arranged is collected and removed. In the tray removal region 12, the many trays 24 are stacked.

Fourth tray transport mechanisms 39 and a fifth tray transport mechanism 41 that transport the trays 24 in the Y directions one by one over the device collection region 16 and the tray removal region 12 are provided. The fourth tray transport mechanisms 39 form a part of the transport section 18 and reciprocate the trays 24 in the Y directions, i.e., directions of thirteenth arrows 39a. The fourth tray transport mechanism 39 transports the tested IC devices 13 from the device collection region 16 to the tray removal region 12. The fifth tray transport mechanism 41 moves the empty tray 24 for collection of the IC devices 13 to the positive side in the Y direction, i.e., a direction of a fourteenth arrow 41a. The fifth tray transport mechanism 41 moves the empty tray 24 from the tray removal region 12 to the device collection region 16.

The control section 4 controls operations of the respective units of the first tray transport mechanism 26, the second transport mechanism 27, the temperature adjustment units 21, the first device transport head 31, the device feed units 22, the tray transport mechanism 32, the test unit 19, the second device transport heads 36, the device collection units 23, the fifth device transport head 37, the third tray transport mechanisms 38, the fourth tray transport mechanisms 39, and the fifth tray transport mechanism 41. The control section 4 has a CPU 42 (Central Processing Unit) and a memory 43. The CPU 42 reads various kinds of information including determination programs and instruction and command programs stored in the memory 43 and executes determinations and commands.

The control section 4 may be provided inside of the electronic component tester 1 or the electronic component handler 2 or provided in an external device such as an external computer. For example, the external device may communicate with the electronic component tester 1 via a cable or the like, wirelessly communicate with the tester, or communicate with the electronic component tester 1 via a network.

In the electronic component tester 1, the tray feed region 11 and the device feed region 14 are divided by a first partition wall 44. The device feed region 14 and the test region 15 are divided by a second partition wall 45. The test region 15 and the device collection region 16 are divided by a third partition wall 46. The device collection region 16 and the tray removal region 12 are divided by a fourth partition wall 47. The device feed region 14 and the device collection region 16 are divided by a fifth partition wall 48.

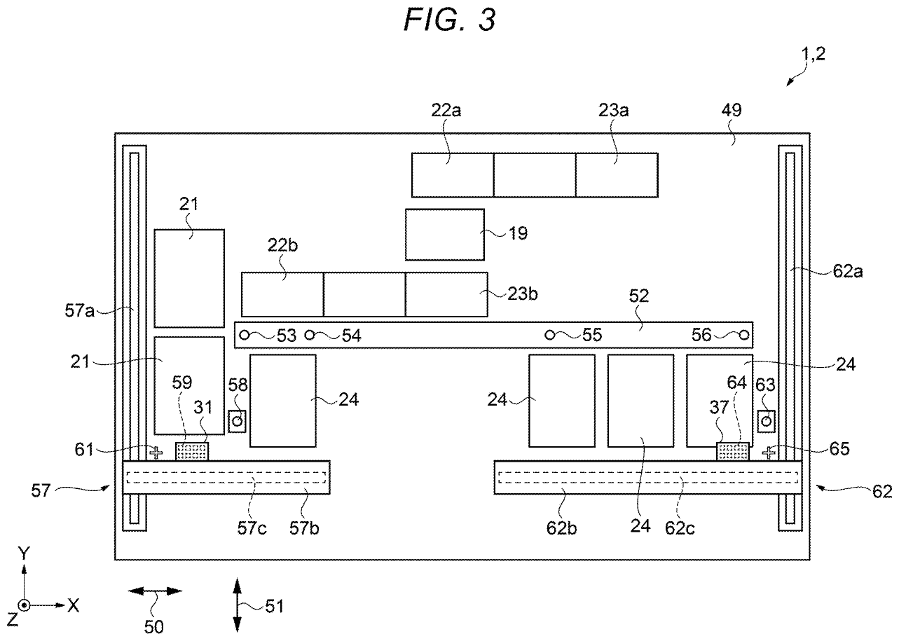

As shown in FIG. 3, the electronic component tester 1 includes a container mount member 49 on which the trays 24 are mounted. An axis parallel to the X-axis is referred to as “first axis 50”. An axis orthogonal to the first axis 50 is referred to as “second axis 51”. The second axis 51 is parallel to the Y-axis. A support member 52 extending along the first axis 50 is placed on the container mount member 49. The support member 52 forms a part of a reinforcing member that supports the container mount member 49. The support member 52 is located substantially at the center of the container mount member 49. The support member 52 is strongly fixed to the container mount member 49. The support member 52 is a framework member suspending the container mount member 49.

The support member 52 includes a first marker 53 as a marker and a second marker 54, a fourth marker 55, and a fifth marker 56 as markers. The respective markers are placed on a center line in the Y directions of the support member 52. The respective markers are placed along the first axis 50.

A first transport robot 57 as a transport robot having the first device transport head 31 is placed at the negative side in the X direction of the container mount member 49. The first transport robot 57 includes a first rail 57a as a second axis guide extending in second axis 51 directions. A first arm 57b is placed on the first rail 57a. The first arm 57b moves along the first rail 57a.

The first arm 57b includes a second rail 57c as a first axis guide extending in first axis 50 directions. The first device transport head 31 is placed on the first arm 57b. The first device transport head 31 moves along the second rail 57c. The first transport robot 57 includes two motors, pulleys fixed to the shafts of the respective motors, and belts looped over the respective pulleys (not shown). The respective belts are fixed to the first arm 57b and the first device transport head 31. The first transport robot 57 drives the respective motors to move the first device transport head 31 in the X directions and the Y directions. The first transport robot 57 has the first device transport head 31 that holds the IC device 13 and moves along the first rail 57a and the second rail 57c.

A third marker 58 as a marker is placed between the temperature adjustment unit 21 and the tray 24 at the negative side in the X direction of the container mount member 49. The first marker 53, the second marker 54, and the third marker 58 are placed within a moving range of the first device transport head 31.

The first device transport head 31 includes a first sensor 59 as a sensor that detects the positions of the respective markers in the X directions and the Y directions and an optical sensor. The first sensor 59 detects the positions of the first marker 53, the second marker 54, and the third marker 58. When energized, the first transport robot 57 moves the first device transport head 31 to a home position. In this regard, a location facing the first sensor 59 is set as a first sensor origin 61 as a reference point. The coordinates of the first marker 53, the second marker 54, and the third marker 58 with reference to the first sensor origin 61 as the origin are measured in advance and stored in the memory 43.

A second transport robot 62 having the fifth device transport head 37 is placed at the positive side in the X direction of the container mount member 49. The second transport robot 62 includes a third rail 62a extending in the second axis 51 directions. A second arm 62b is placed on the third rail 62a. The second arm 62b moves along the third rail 62a.

The second arm 62b includes a fourth rail 62c extending in the first axis 50 directions. The fifth device transport head 37 is placed on the second arm 62b. The fifth device transport head 37 moves along the fourth rail 62c. The second transport robot 62 includes two motors, pulleys fixed to the shafts of the respective motors, and belts looped over the respective pulleys (not shown). The respective belts are fixed to the second arm 62b and the fifth device transport head 37. The second transport robot 62 drives the respective motors to move the fifth device transport head 37 in the X directions and the Y directions. The second transport robot 62 has the fifth device transport head 37 that holds the IC device 13 and moves along the third rail 62a and the fourth rail 62c. The support member 52 serves as a reference for the first rail 57a, the second rail 57c, the third rail 62a, and the fourth rail 62c.

A sixth marker 63 is placed between the tray 24 and the third rail 62a at the positive side in the X direction of the container mount member 49. The fourth marker 55, the fifth marker 56, and the sixth marker 63 are placed within the moving range of the fifth device transport head 37.

The fifth device transport head 37 includes a second sensor 64 as a sensor that detects the positions of the respective markers in the X directions and the Y directions and an optical sensor. The second sensor 64 detects the positions of the fourth marker 55, the fifth marker 56, and the sixth marker 63. When energized, the second transport robot 62 moves the fifth device transport head 37 to a home position. In this regard, a location facing the second sensor 64 is set as a second sensor origin 65. The coordinates of the fourth marker 55, the fifth marker 56, and the sixth marker 63 with reference to the second sensor origin 65 as the origin are measured in advance and stored in the memory 43.

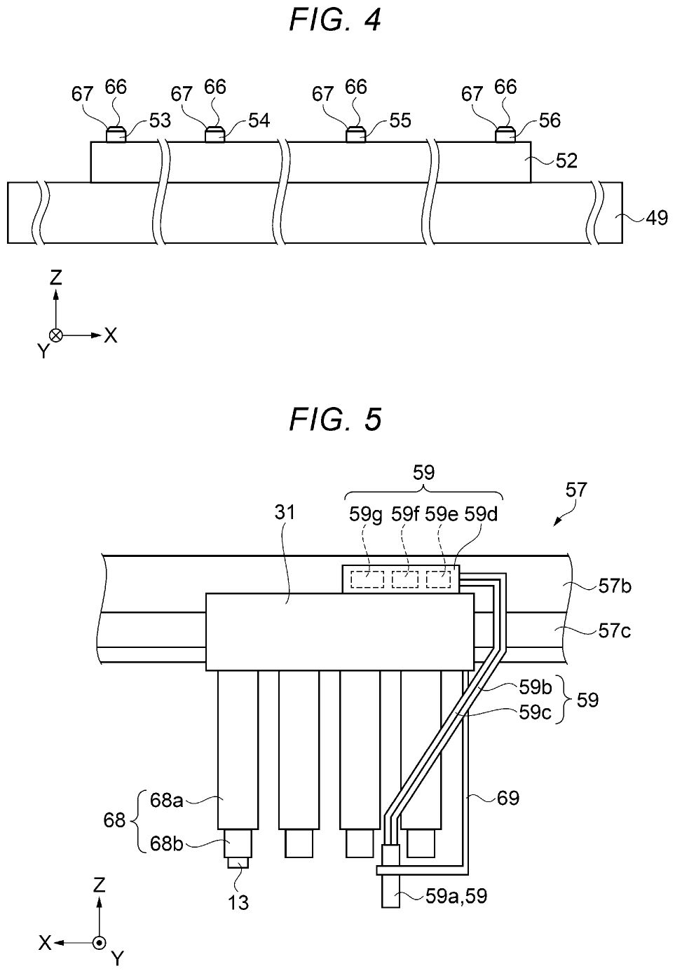

As shown in FIG. 4, the first marker 53, the second marker 54, the fourth marker 55, and the fifth marker 56 are cylindrical convex portions. Further, the third marker 58 and the sixth marker 63 are cylindrical convex portions. The first marker 53 to the sixth marker 63 include inclined surfaces 67 coupling to facing surfaces 66 facing the first sensor 59 and the second sensor 64.

As shown in FIG. 5, the first device transport head 31 includes holding hands 68 that hold the IC devices 13. The holding hands 68 are arranged in two rows and four columns. The holding hand 68 includes an elevating portion 68a and a suction portion 68b. The elevating portion 68a includes a linear motion mechanism and moves upward and downward the suction portion 68b in the Z directions. The suction portion 68b is coupled to a decompression pump (not shown) by a pipe and suctions and holds the IC device 13.

The first sensor 59 includes an objective lens 59a, a lighting fiber 59b, a receiving fiber 59c, and a sensor controller 59d. The sensor controller 59d includes an LED 59e (light emitting diode), a phototransistor 59f, and a sensor drive unit 59g. The sensor drive unit 59g is a circuit that drives the LED 59e and the phototransistor 59f. The objective lens 59a is fixed to the first device transport head 31 by a supporting member 69.

The light emitted by the LED 59e passes through the lighting fiber 59b and the objective lens 59a and radiates the first marker 53 to the sixth marker 63 etc. The light reflected by the first marker 53 to the sixth marker 63 etc. passes through the receiving fiber 59c and radiates the phototransistor 59f. An amount of light received by the phototransistor 59f is converted into an analog electrical signal and output to the sensor drive unit 59g. The sensor drive unit 59g converts the analog electrical signal into a digital electrical signal and outputs the signal to the CPU 42.

The first sensor 59 is the optical sensor that constantly emits light. The first sensor 59 outputs light and detects the light reflected by the first marker 53 to the sixth marker 63. The temperatures of the LED 59e and the phototransistor 59f may be maintained at fixed temperatures, and thereby, the first marker 53 to the sixth marker 63 may be accurately detected. The frequency of turning on and off of the optical sensor is lower, and the control may be easier. Note that the first sensor 59 and the second sensor 64 have the same structure.

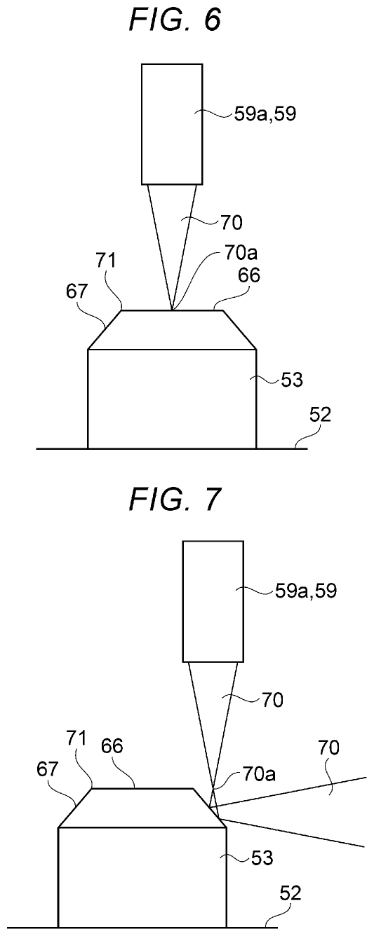

As shown in FIG. 6, when the position of the first marker 53 is detected, a light 70 is radiated from the objective lens 59a. The light 70 is focused by the objective lens 59a. The location where the light is focused is referred to as “focus point 70a”. The first transport robot 57 brings the focus point 70a closer to the facing surface 66 of the first marker 53. The facing surface 66 is a mirror surface and an amount of the light 70 reflected toward the objective lens 59a is larger.

As shown in FIG. 7, the first transport robot 57 moves the first sensor 59 while maintaining the position of the focus point 70a in the Z directions. The first marker 53 has the inclined surface 67 around an edge 71 as an outer circumference of the facing surface 66. The focused light 70 radiates the inclined surface 67. Then, the light 70 is reflected by the inclined surface 67 and changes the traveling direction thereof. The reflected light 70 does not travel to the objective lens 59a, and an amount of the light 70 radiating the objective lens 59a is smaller.

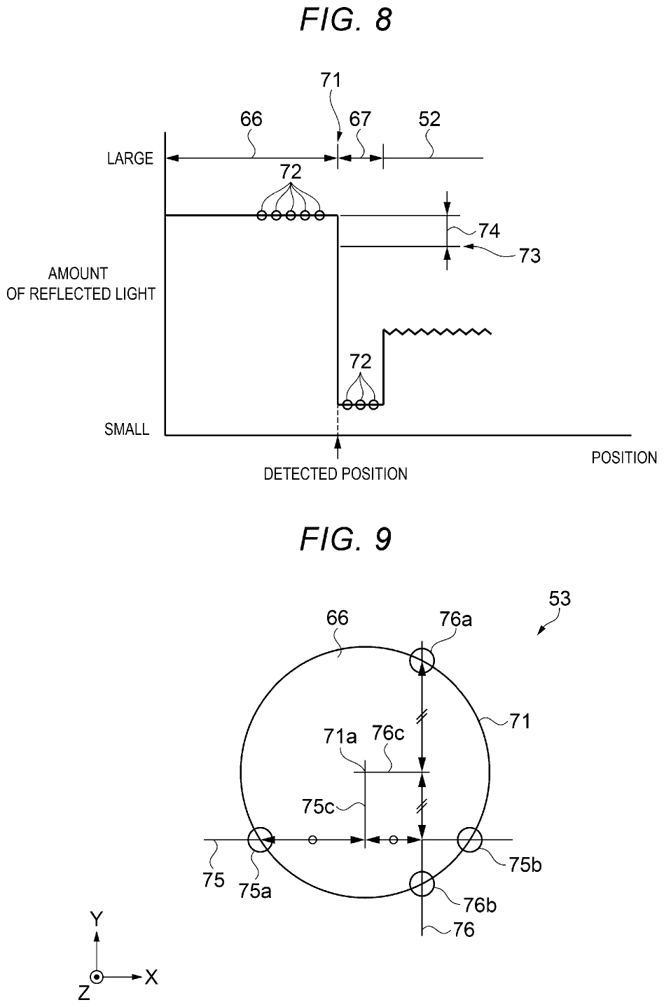

In FIG. 8, the horizontal axis indicates the position where the focus point 70a moves. The vertical axis indicates the amount of the light 70 received by the phototransistor 59f. When the light 70 radiates the facing surface 66, the amount of the reflected light is larger. When the light 70 radiates the inclined surface 67, the amount of the reflected light is smaller.

A plurality of amounts of light received by the first sensor 59 are detected at detection points 72 as a plurality of locations over the edge 71 of the first marker 53. The first sensor 59 sets a determination value 73 for detection of the edge 71 of the first marker 53 using an average value of the plurality of detected amounts of light. Specifically, the amounts of light are detected at the plurality of detection points 72 on the facing surface 66 and an average value is calculated. Then, the amounts of light are detected at the plurality of detection points 72 on the inclined surface 67 and an average value is calculated. Then, a value obtained by subtraction of the average value of the amounts of light on the inclined surface 67 from the average value of the amounts of light on the facing surface 66 and division by a predetermined number is referred to as “determination range 74”. A value obtained by subtraction of the determination range 74 from the amount of the reflected light by the facing surface 66 is set as the determination value 73. Note that the predetermined number used for division for the calculation of the determination range 74 is set with reference to a distribution of the reflected light.

According to the method, the amount of the light 70 received by the first sensor 59 of the light 70 reflected by the facing surface 66 of the first marker 53 is detected. The light 70 reflected by the inclined surface 67 outside of the first marker 53 is received by the first sensor 59 and the amount of the light 70 is detected. A middle amount of the detected amount of light is set as the determination value 73. The first sensor 59 detects the edge 71 of the first marker 53 using the set determination value 73. Therefore, the edge 71 is detected according to the reflection state of the first marker 53, and thereby, the first sensor 59 may be accurately detected.

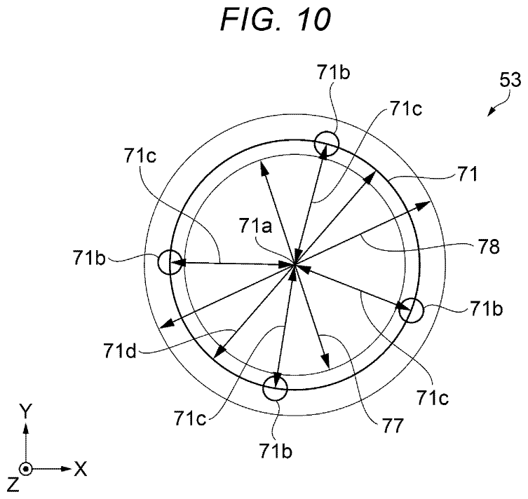

Next, a method of detecting coordinates of the first marker 53 is explained. As shown in FIG. 9, the edge 71 of the facing surface 66 of the first marker 53 has a circular shape and the coordinates of the first marker 53 indicate a center 71a of the edge 71. First, the first transport robot 57 moves the first sensor 59 in the X directions. A trajectory of the focus point 70a passing through the facing surface 66 of the first sensor 59 is referred to as “first trajectory 75”. Two points at which the first trajectory 75 and the edge 71 intersect are referred to as “first intersection point 75a” and “second intersection point 75b”. The first sensor 59 detects the first intersection point 75a and the second intersection point 75b.

Then, the first transport robot 57 moves the first sensor 59 in the Y directions. A trajectory of the focus point 70a passing through the facing surface 66 of the first sensor 59 is referred to as “second trajectory 76”. Two points at which the second trajectory 76 and the edge 71 intersect are referred to as “third intersection point 76a” and “fourth intersection point 76b”. The first sensor 59 detects the third intersection point 76a and the fourth intersection point 76b.

A perpendicular bisector of the first intersection point 75a and the second intersection point 75b in the first trajectory 75 is referred to as “first line segment 75c”. A perpendicular bisector of the third intersection point 76a and the fourth intersection point 76b in the second trajectory 76 is referred to as “second line segment 76c”. The CPU 42 calculates and sets an intersection point between the first line segment 75c and the second line segment 76c as the center 71a of the edge 71.

As shown in FIG. 10, then, the first sensor 59 detects a plurality of on-edge points 71b detected on the edge 71. Then, the CPU 42 calculates radii 71c at the plurality of on-edge points 71b. The CPU 42 calculates an average value of the radii 71c and doubles the average value and obtains a diameter 71d. As described above, the CPU 42 detects a plurality of coordinates of the edge 71 of the first marker 53 having a circular planar shape. Then, the diameter 71d of the first marker 53 is calculated from the plurality of coordinates of the edge 71.

The CPU 42 compares the diameter 71d with a first determination value 77 and a second determination value 78. When the diameter 71d of the first marker 53 is smaller than the first determination value 77 or larger than the second determination value 78, a plurality of coordinates of the edge 71 of the first marker 53 are redetected and the center 71a is detected again.

According to the method, the electronic component handler 2 detects the plurality of coordinates of the edge 71 of the first marker 53 and calculates the diameter 71d of the first marker 53. When the measured diameter 71d of the first marker 53 is not within a normal range, the diameter 71d of the first marker 53 is measured again. Therefore, the position of the first marker 53 may be reliably detected.

The CPU 42 detects the coordinates of the second marker 54 to the sixth marker 63 using the same method as the method of detecting the coordinates of the first marker 53.

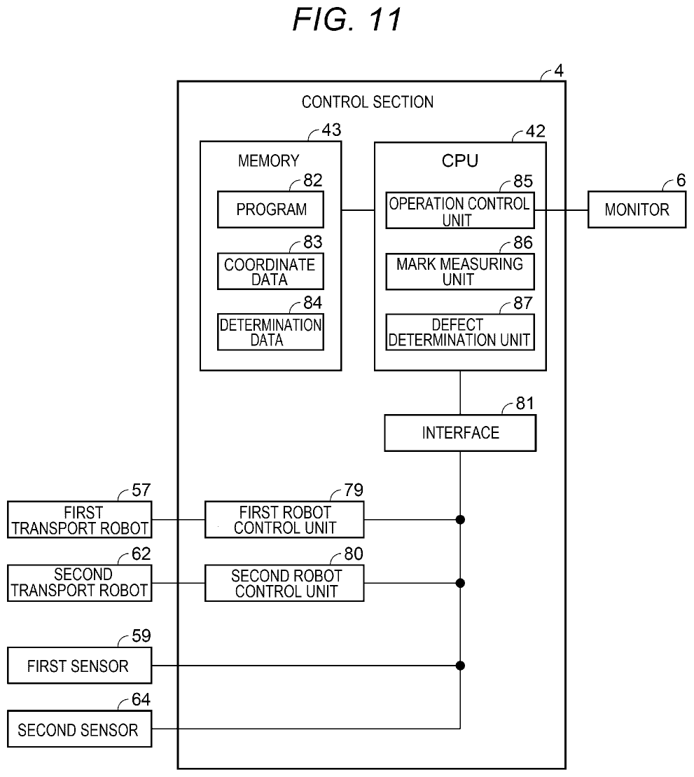

As shown in FIG. 11, the control section 4 includes the CPU 42 that performs various kinds of calculation processing as a processor and the memory 43 that stores various kinds of information. A first robot control unit 79, a second robot control unit 80, the first sensor 59, and the second sensor 64 are electrically coupled to the CPU 42 via an interface 81.

The first robot control unit 79 controls the operation of the first transport robot 57. The first robot control unit 79 moves the first device transport head 31 to a location instructed according to an instruction signal input from the CPU 42.

The second robot control unit 80 controls the operation of the second transport robot 62. The second robot control unit 80 moves the fifth device transport head 37 to a location instructed according to an instruction signal input from the CPU 42.

The memory 43 has a concept including a semiconductor memory such as a RAM or ROM and an external memory device such as a hard disc. The memory 43 stores a program 82 in which control procedures of the operation of the electronic component handler 2, determination procedures of defective transport, etc. are described. Further, the memory 43 stores coordinate data 83 output by the first sensor 59 and the second sensor 64. Furthermore, the memory 43 stores determination data 84 including the first determination value 77 and the second determination value 78 for determination of data.

The CPU 42 controls the operation of the electronic component handler 2 according to the program 82 stored within the memory 43. The CPU 42 has various functional units for realizing functions. As a specific functional unit, the CPU 42 has an operation control unit 85. The operation control unit 85 provides instructions on movement destinations and movement times of the first device transport head 31 and the fifth device transport head 37.

Further, the CPU 42 has a mark measuring unit 86. The mark measuring unit 86 calculates the positions of the first marker 53 to the sixth marker 63. Furthermore, the CPU 42 has a defect determination unit 87. The defect determination unit 87 determines whether or not the first transport robot 57 and the second transport robot 62 are normal.

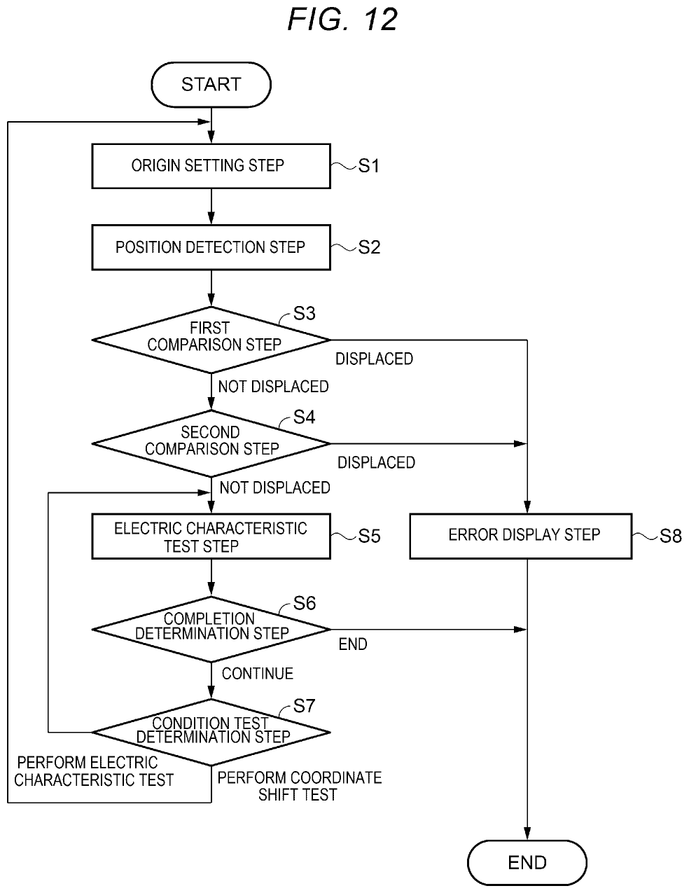

Next, a method of checking a condition of the electronic component handler 2 will be explained. A condition check of the transfer robot including the second transport robot 62 is performed in the same manner as that of the first transport robot 57. The method for the first transport robot 57 will be explained and the explanation of the methods of checking the conditions of the other transport robots will be omitted. In FIG. 12, step S1 is an origin setting step. At this step, the first device transport head 31 of the first transport robot 57 is moved to a reference position on the second rail 57c along the first axis 50. Then, the first device transport head 31 of the first transport robot 57 is moved to a reference position on the first rail 57a extending along the second axis 51 orthogonal to the first axis 50. Then, the first sensor origin 61 of the first sensor 59 of the first transport robot 57 is set in a reference position of the first device transport head 31.

According to the method, the first device transport head 31 of the first transport robot 57 is moved to the reference position on the second rail 57c along the first axis 50 and moved to the reference position on the first rail 57a along the second axis 51. Then, the first sensor origin 61 of the first sensor 59 is set in the reference position. Therefore, the first sensor origin 61 corresponds to the reference position of the first device transport head 31, and thereby, displacement of the first device transport head 31 may be accurately detected. Then, the process moves to step S2.

Step S2 is a position detection step. At this step, the first sensor 59 of the first transport robot 57 detects the position of the first marker 53 of the support member 52 and outputs the position as first measurement coordinates to the control section 4. Then, the first sensor 59 of the first transport robot 57 detects the position of the second marker 54 of the support member 52 and outputs the position as second measurement coordinates to the control section 4. Then, the first sensor 59 of the first transport robot 57 detects the position of the third marker 58 and outputs the position as third measurement coordinates to the control section 4. The CPU 42 stores the coordinate data 83 of the first measurement coordinates, the second measurement coordinates, and the third measurement coordinates in the memory 43. Then, the process moves to step S3.

Step S3 is a first comparison step. At this step, the defect determination unit 87 of the control section 4 compares the first reference coordinates stored in advance with the first measurement coordinates. Further, the defect determination unit 87 compares the second reference coordinates stored in advance with the second measurement coordinates. Furthermore, the defect determination unit 87 compares the third reference coordinates stored in advance with the third measurement coordinates. The comparison between coordinates includes a comparison between X-coordinates and a comparison between Y-coordinates.

When a difference between the first reference coordinates and the first measurement coordinates is equal to or larger than a predetermined value, the defect determination unit 87 determines that the first device transport head 31 of the first transport robot 57 is displaced. Further, when a difference between the second reference coordinates and the second measurement coordinates is equal to or larger than a predetermined value, the defect determination unit 87 determines that the first device transport head 31 of the first transport robot 57 is displaced. Furthermore, when a difference between the third reference coordinates and the third measurement coordinates is equal to or larger than a predetermined value, the defect determination unit 87 determines that the first device transport head 31 of the first transport robot 57 is displaced. When the defect determination unit 87 determines that the first device transport head 31 of the first transport robot 57 is displaced, defect information is output to the monitor 6 and the process moves to step S8.

When the difference between the first reference coordinates and the first measurement coordinates is smaller than the predetermined value, the difference between the second reference coordinates and the second measurement coordinates is smaller than the predetermined value, and the difference between the third reference coordinates and the third measurement coordinates is smaller than the predetermined value, the defect determination unit 87 determines that the first device transport head 31 of the first transport robot 57 is not displaced and the process moves to step S4.

Step S4 is a second comparison step. At this step, the defect determination unit 87 of the control section 4 compares first axis components between the first measurement coordinates and the second measurement coordinates. When a difference between the first axis components of the first measurement coordinates and the second measurement coordinates is equal to or larger than a predetermined value, the defect determination unit 87 determines that the first device transport head 31 of the first transport robot 57 is displaced, and then, defect information of axis misalignment is output to the monitor 6 at step S8. When the difference between the first axis components of the first measurement coordinates and the second measurement coordinates is smaller than the predetermined value, the defect determination unit 87 determines that the first device transport head 31 of the first transport robot 57 is not displaced, and then, the process moves to step S5.

Step S5 is an electric characteristic test step. This step is a step of sequentially transporting the IC devices 13 to the test unit 19 by the transport section 18 and performing electric characteristic tests. Then, the process moves to step S6.

Step S6 is a completion determination step. This step is a step of determining whether or not all of the scheduled electric characteristic tests of the IC devices 13 are completed. When all of the scheduled electric characteristic tests of the IC devices 13 are completed, the step of performing the electric characteristic test of the IC device 13 is ended. When the scheduled electric characteristic test of the IC device 13 remains, the process moves to step S7.

Step S7 is a condition test determination step. This step is a step of determining whether or not to perform a condition test. When a ratio of a number of IC devices 13 not properly mounted on the tray 24 or the temperature adjustment unit 21 to a number of IC devices 13 transported by the first transport robot 57 exceeds a defect determination value, the process moves to step S1 for condition check of the first transport robot 57.

When the first transport robot 57 does not normally operate or when the electronic component handler 2 starts an operation, the process moves to step S1 for condition check of the first transport robot 57. When the first transport robot 57 normally operates, the process moves to step S1 and continues the electric characteristic test. At the above described step, the process including the step of checking the condition of the first transport robot 57 is ended.

According to the configuration of the electronic component handler 2, the support member 52 forms the part of the reinforcing member that supports the container mount member 49, has the shape extending along the first axis 50, and is undetachably fixed. Therefore, the first marker 53 and the second marker 54 provided on the support member 52 serve as markers for an accurate position as a reference for the first axis 50. The positions of the first marker 53 and the second marker 54 are detected by the first sensor 59 of the first device transport head 31, and thereby, displacement of the first device transport head 31 with respect to the first axis 50 may be accurately detected. Thus, when the first device transport head 31 is displaced with respect to the first axis 50, the need to repair the first device transport head 31 and reteach alignment may be determined. Therefore, the electronic component handler 2 that may accurately detect the displacement of the first device transport head 31 with respect to the first axis 50 may be provided.

According to the configuration of the electronic component handler 2, the first marker 53 to the sixth marker 63 have the cylindrical shapes. A center of a circle is easily detected, and the positions of the first marker 53 to the sixth marker 63 may be easily detected.

According to the configuration of the electronic component handler 2, the first marker 53 to the sixth marker 63 include the facing surfaces 66 and the inclined surfaces 67. Part of the light 70 output by the first sensor 59 is reflected by the facing surface 66 and radiates the first sensor 59. The light 70 radiating the inclined surface 67 changes in traveling direction, and does not return to the first sensor 59. Therefore, the edge 71 coupling the facing surface 66 and the inclined surface 67 may be easily detected.

The electronic component tester 1 includes the electronic component handler 2. Even when the first device transport head 31 contacts an object, the above described electronic component handler 2 detects displacement, and thereby, repairing of the first device transport head 31 and reteaching for alignment may be performed. Therefore, even when the first device transport head 31 contacts an object, the electronic component tester 1 detects displacement, and thereby, repairing of the first device transport head 31 and reteaching for alignment may be performed.

According to the method, the first marker 53 and the second marker 54 are provided on the support member 52. The first measurement coordinates are the coordinates of the position of the first marker 53 detected by the first sensor 59 of the first transport robot 57. When the difference between the first reference coordinates and the first measurement coordinates is equal to or larger than the predetermined value, the control section 4 outputs displacement of the first device transport head 31 of the first transport robot 57 to the monitor 6.

The first marker 53 and the second marker 54 are placed on the line parallel to one axis along which the first device transport head 31 moves. The second measurement coordinates are the coordinates of the position of the second marker 54 detected by the first sensor 59 of the first transport robot 57.

When the difference between the first axis components of the first measurement coordinates and the second measurement coordinates is equal to or larger than the predetermined value, the control section 4 outputs displacement of the first device transport head 31 of the first transport robot 57 to the monitor 6. The first marker 53 and the second marker 54 are placed on the support member 52, and changes in relative position with respect to the coordinate origins are smaller. Therefore, the displacement of the first device transport head 31 may be reliably detected.

When the ratio of the number of IC devices 13 not properly mounted on the container to the number of IC devices 13 transported by the first transport robot 57 exceeds the defect determination value, the first device transport head 31 is likely to be displaced. When the first transport robot 57 does not normally operate, the first device transport head 31 is likely to be displaced. When the electronic component handler 2 starts an operation, the first device transport head 31 is likely to be displaced. When the first device transport head 31 is likely to be displaced, a condition check of the electronic component handler 2 is performed. Then, when the first device transport head 31 is displaced with respect to the first axis 50, repairing of the first device transport head 31 and reteaching for alignment may be performed. Therefore, the electronic component handler 2 may be reliably actuated.

### Second Embodiment

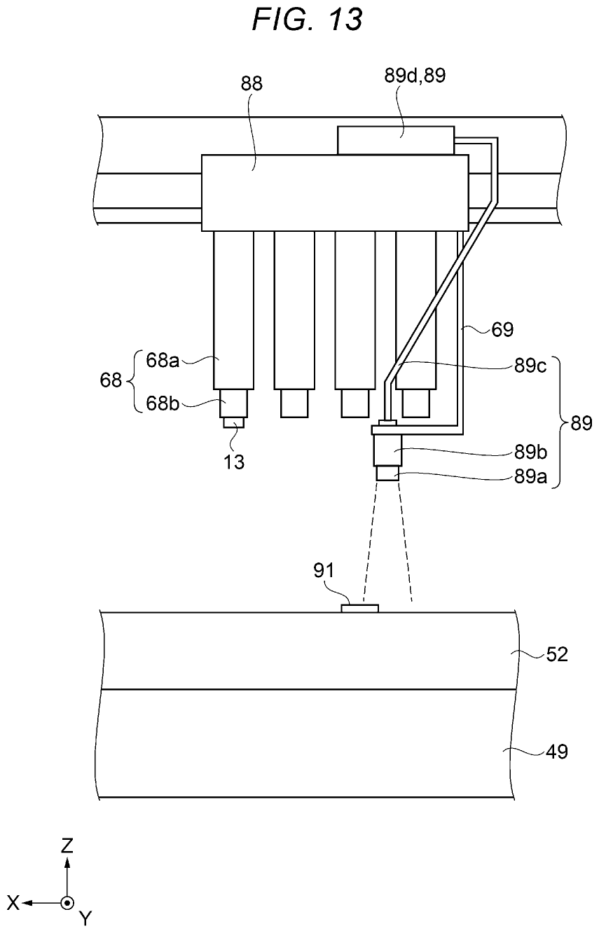

This embodiment is different from the first embodiment in that a camera is used in place of the first sensor 59. The same configurations as those of the first embodiment have the same signs and the overlapping explanation will be omitted. As shown in FIG. 13, a first device transport head 88 as a moving unit includes a camera 89 as a sensor that detects the positions of the respective markers in the X directions and the Y directions and an optical sensor. The camera 89 detects a position of a seventh marker 91 as a marker. The seventh marker 91 corresponds to the first marker 53 and the second marker 54.

The camera 89 includes an objective lens 89a, a solid-state image sensing device 89b, a coupling wire 89c, and a camera controller 89d. The solid-state image sensing device 89b is a two-dimensional sensor and images a planar shape of the seventh marker 91. The solid-state image sensing device 89b transmits a picture signal to the camera controller 89d via the coupling wire 89c. The camera controller 89d transforms the picture signal into a still image and digitally converts and outputs the image to the CPU 42.

The seventh marker 91 is colored in a different color from the surrounding part. Therefore, the seventh marker 91 and the support member 52 as a background may be easily distinguished. The seventh marker 91 has a form of a coated film, a thin film, or attachment of a dye formed on the support member 52 and does not project from the support member 52, and thereby, interferences with the camera 89 may be suppressed. The seventh marker 91 is a circular figure. The markers corresponding to the second marker 54 to the sixth marker 63 are the same circular figures as the seventh marker 91. Therefore, the center of the figure may be easily calculated.

The shape of the seventh marker 91 may be a spherical shape, a square shape, a polygonal shape, or a cross shape. The shape of the seventh marker 91 is preferably a longitudinally and laterally symmetrical shape. The center of the figure may be easily calculated.

### Third Embodiment

The first marker 53 to the sixth marker 63 of the first embodiment have the cylindrical shapes. Or, the first marker 53 to the sixth marker 63 may be circular concave portions. The center of a circle is easily detected, and the positions of the markers may be easily detected. The circular concave portions are easily formed, and the markers may be formed with higher productivity. The concave portions may have inclined surfaces between upper surfaces facing in the Z directions and side surfaces. Or, the first marker 53 to the sixth marker 63 may be non-circular concave portions. Inclined surfaces may be provided between upper surfaces and side surfaces of the concave portions. For example, the first marker 53 to the sixth marker 63 may be square concave portions.

Or, the first marker 53 to the sixth marker 63 may be figures that provide different amounts of reflected light. Or, the first marker 53 to the sixth marker 63 may be three-dimensional structures having differences in height. The three-dimensional structures may have inclined surfaces between upper surfaces facing in the Z directions and side surfaces. For example, the first marker 53 to the sixth marker 63 may be quadrangular prism projections. The marker 53 to the sixth marker 63 may be colored in different colors from that of the surrounding part. The marker 53 to the sixth marker 63 may include mirror surfaces. According to the configurations, the first sensor 59, the second sensor 64, and the camera 89 may easily detect the markers.

### Fourth Embodiment

In the first embodiment, the first reference coordinates previously stored by the defect determination unit 87 and the first measurement coordinates are compared. Further, the second reference coordinates previously stored by the defect determination unit 87 and the second measurement coordinates are compared. Furthermore, the third reference coordinates previously stored by the defect determination unit 87 and the third measurement coordinates are compared.

Only the comparison between the first reference coordinates and the first measurement coordinates may be performed. Or, only the comparison between the second reference coordinates and the second measurement coordinates may be performed. Or, only the comparison between the third reference coordinates and the third measurement coordinates may be performed.

Or, two of the comparison between the first reference coordinates and the first measurement coordinates and the comparison between the second reference coordinates and the second measurement coordinates may be performed. Or, two of the comparison between the first reference coordinates and the first measurement coordinates and the comparison between the third reference coordinates and the third measurement coordinates may be performed. Or, two of the comparison between the second reference coordinates and the second measurement coordinates and the comparison between the third reference coordinates and the third measurement coordinates may be performed.

### Fifth Embodiment

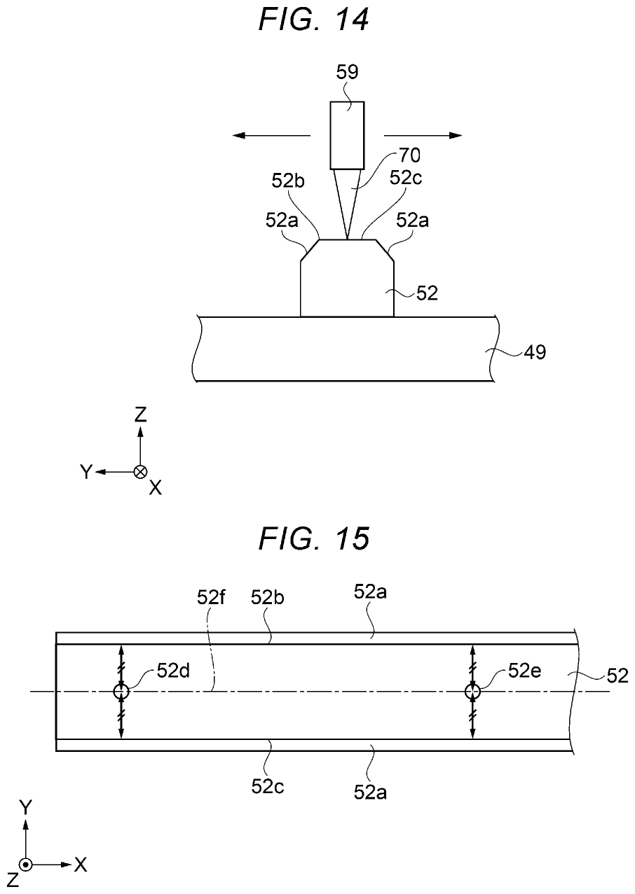

In the first embodiment, the directions in which the support member 52 extends are detected using the first marker 53 and the second marker 54. The center of the support member 52 in the Y directions may be detected without using the first marker 53 and the second marker 54. As shown in FIG. 14, in the support member 52, inclined surfaces 52a are formed on side surfaces at the positive side in the Y direction and the negative side in the Y direction. The first sensor 59 is moved in the Y directions and a first edge 52b at the positive side in the Y direction and a second edge 52c at the negative side in the Y direction are detected.

As shown in FIG. 15, then, coordinates of a first middle point 52d as a middle point between the first edge 52b and the second edge 52c are calculated. Then, the first sensor 59 is moved to the positive side in the X direction and the first edge 52b and the second edge 52c are similarly detected. Furthermore, a second middle point 52e as a middle point between the first edge 52b and the second edge 52c is calculated. A line passing through the first middle point 52d and the second middle point 52e is referred to as “support member center line 52f”. The support member center line 52f is along directions in which the support member 52 extends. The support member center line 52f is compared with a reference line stored in advance. When an angle formed by the reference line and the support member center line 52f is equal to or larger than a determination angle, the control section 4 outputs displacement of the first device transport head 31 of the first transport robot 57 to the monitor 6. The support member 52 is strongly fixed to the container mount member 49, and a change in relative position with respect to the coordinate origin is smaller. Therefore, the displacement of the first device transport head 31 may be reliably detected.

In the method, the support member 52 has the function of the markers. The first marker 53 and the second marker 54 are not formed, and thus, the electronic component handler 2 may be manufactured with higher productivity.

What is claimed is:

1. An electronic component handler comprising:
a container mount member on which a container with an electronic component mounted thereon is placed;
a support member supporting the container mount member and extending along a first axis;
a transport robot having a moving unit that holds the electronic component and moves; and
a sensor placed in the moving unit, wherein
a marker is provided on the support member and the sensor detects a position of the marker.

2. The electronic component handler according to claim 1, wherein
the marker is a cylindrical convex portion.

3. The electronic component handler according to claim 1, wherein
the marker is a circular concave portion.

4. The electronic component handler according to claim 1, wherein
the sensor outputs a light and detects the light reflected by the marker, and
the marker includes an inclined surface coupling to a facing surface facing the sensor.

5. The electronic component handler according to claim 1, wherein
the marker has a different color from that of a surrounding part.

6. An electronic component tester comprising:
a test unit that tests the electronic component; and
the electronic component handler according to claim 1.

7. A method of checking a condition of an electronic component handler that transports an electronic component, comprising:
detecting and outputting a position of a first marker of a support member as a first measurement coordinate to a control section by a sensor of a transport robot;
comparing a first reference coordinate stored in advance with the first measurement coordinate by the control section;
detecting and outputting a position of a second marker of the support member as a second measurement coordinate to the control section by the sensor of the transport robot;
comparing first axis components between the first measurement coordinate and the second measurement coordinate by the control section; and
when a difference between the first measurement coordinate and the first reference coordinate is equal to or larger than a predetermined value or when a difference between the first axis components of the first measurement coordinate and the second measurement coordinate is equal to or larger than a predetermined value, outputting a condition in which a moving unit of the transport robot is displaced.

8. The method of checking the condition of the electronic component handler according to claim 7, further comprising:
detecting a plurality of coordinates at an edge of the first marker having a circular planar shape;
calculating a diameter of the first marker from the plurality of coordinates; and
when the diameter of the first marker is smaller than a first determination value or larger than a second determination value, redetecting the plurality of coordinates at the edge of the first marker.

9. The method of checking the condition of the electronic component handler according to claim 7, further comprising:
moving the moving unit of the transport robot to a reference position of a first axis guide extending along a first axis;
moving the moving unit of the transport robot to a reference position of a second axis guide extending along a second axis orthogonal to the first axis; and
setting a reference point of the sensor of the transport robot in a reference position.

10. The method of checking the condition of the electronic component handler according to claim 8, wherein
the sensor is an optical sensor,
further comprising:
detecting a plurality of amounts of light received by the optical sensor in a plurality of locations over the edge of the first marker; and
setting a determination value for detection of the edge of the first marker by the optical sensor using an average value of the plurality of amounts of light.
